(19) United States
(12) Patent Application Publication
(10) Pub. No.: US 2006/0236559 A1
(43) Pub. Date: Oct. 26, 2006

(54) Method for drying material to be heated, heating furnace, and method for manufacturing device

(75) Inventor: Toshimasa Mori, Shimo Suwa-machi (JP)

Correspondence Address: GLOBAL IP COUNSELORS, LLP, 1233 20TH STREET, NW, SUITE 700, WASHINGTON, DC, 20036-2680, US

(73) Assignee: Seiko Epson Corporation, Shinjuku-ku (JP)

(21) Appl. No.: 11/299,678

(22) Filed: Dec. 13, 2005

(30) Foreign Application Priority Data
Dec. 16, 2004 (JP) 2004-364102

(51) Int. Cl. F26B 7/00

(52) U.S. Cl. 34/380

(57) ABSTRACT

A heating furnace includes a housing chamber adapted to house a heating object, a heater for heating the heating object housed in the housing chamber, a vacuum pump for reducing a pressure inside the housing chamber, a pressure detector for detecting the pressure inside the housing chamber; a leakage detector for detecting any leak current that is caused by reducing the pressure inside the housing chamber while power is supplied to the heater; and a controller for switching the power to the heater on or off on the basis of detection results from the pressure detector and the leakage detector.

### BACKGROUND

1. Technical Field

The present invention relates to a method for drying a material to be heated, a heating furnace, and a method for manufacturing a device.

2. Related Art

Various display devices (electro-optical devices) are generally provided with color filters to make color display possible. These color filters, for example, include dot-shaped filter elements of red (R), green (G), and blue (B) arranged in a specific arrangement pattern (such as what are called a striped array, a delta array, or a mosaic array) on a substrate made of glass, plastic, or the like.

To use an electro-optical device such as a liquid crystal device or electroluminescent (EL) device as an example of a display device, display dots whose optical state can be independently controlled are arranged over a substrate made of glass, plastic, or the like. In this case, liquid crystals or EL light emitting components are provided for the display dots. The layout of the display dots is generally in the form of a vertical and horizontal lattice (dot matrix), for example.

A display device capable of full-color display is usually configured, for example, such that display dots (liquid crystals or EL light emitting components) are formed corresponding to the above-mentioned R, G, and B colors, and a single pixel of three display dots, for instance, corresponding to all colors. A color display can be accomplished by controlling the gradation of the display dots included in a single pixel.

As disclosed in JP-A-2003-279245, for example, these display devices are sometimes manufactured by a method in which a substrate is coated with a photosensitive resin, and this photosensitive resin is subjected to exposure and development treatments, which forms a lattice-like barrier (bank), after which droplets discharged from a head or the like are made to land in the regions bounded by this barrier and dried to form display elements (that is, the display dots of an EL light emitting component, or the filter elements of the above-mentioned color filter). With this method, the display elements do not have to be lithographically patterned for each color, so an advantage is that manufacturing thereof is easier. Also, the coating film of liquid material applied over the substrate was subjected to vacuum heating and drying to make the thickness of the films uniform (see JP-A-2003-279245, for example).

However, the above known method for manufacturing a color filter or display device (electro-optical device) almost always involves using a liquid-repellent material to form a barrier component called a bank around the pixel region; a functional liquid (a liquid material) is disposed within this bank, and the functional liquid is dried using a heating furnace that allows the degree of vacuum to be varied while the temperature inside the furnace is controlled so that the coating film will be uniform. This heating furnace employs a reduced pressure heating and drying method that allows the degree of vacuum in the furnace to be raised (the pressure to be lowered) while the inside of the furnace is heated. It was found that, when the furnace is under a specific degree of vacuum while such a heater is operated, current leakage occurs from the wiring portion when current flows to the heater. Furthermore, it was found that even if the degree of vacuum is raised (the pressure lowered) while current flows to the heater and the inside of the furnace is heated, there is current leakage from the wiring portion when the degree of vacuum is within a specific range. How this happens is as follows. As the pressure in the furnace is lowered, just a few electrons are extracted at the cathode of the heater, and these electrons flow toward the positive electrode (anode). Along the way, they collide with gas molecules, knocking electrons loose from these molecules. These electrons flow into the anode. Meanwhile, positive ions are attracted to the anode. The anode knocks electrons loose at -this point (the principle of sputtering). Discharge is maintained by repetition of this process. This phenomenon occurs not only between electrodes, but also between an electrode and the furnace (SUS) or another metal, and this is a cause of leakage. As the pressure is further lowered (the degree of vacuum raised), the number of gas molecules decreases, and there is a sharp reduction in the number of ions, which brings discharge to a halt and eliminates leakage.

Once the value of this leak current reaches 100 mA, the heating furnace would be shut down by an attached leakage blocker to prevent any harmful effect to humans. When the heating furnace is shut down, a color filter or display device (electro-optical device) in the middle of a drying process would end up being defective because of incomplete drying.

### SUMMARY

It is an advantage of the invention to provide a drying method, a heating furnace, and a device manufacturing method with which leak current can be prevented from affecting humans when an object to be heated is heated and dried under reduced pressure, and furthermore, the drying treatment can be continued without interruption.

The heating furnace of an aspect of the invention includes a housing chamber a housing chamber adapted to house a heating object, a heater for heating the heating object housed in the housing chamber, a vacuum pump for reducing the pressure inside the housing chamber, a pressure detector for detecting the pressure inside the housing chamber, a leakage detector for detecting any leak current that is caused by reducing the pressure inside the housing chamber while power is supplied to the heater, and a controller for switching the power to the heater on or off on the basis of the detection results from the pressure detector and the leakage detector.

With this aspect of the invention, as the interior of the housing chamber is heated while the pressure is reduced, the heater can be cut off from its power supply on the basis of the detection result from the leakage detector before the leak current generated by the heating furnace reaches its maximum permissible value. Also, the heater can be reconnected to its power supply on the basis of the detection result from the pressure detector.

With the heating furnace of this aspect of the invention, it is preferable if the controller stops the flow of power to the heater while the heating furnace is within a discharge region, which is a reduced pressure region in which at least the leak current exceeds a permissible value during a pressure reduction process to reduce the pressure inside the housing chamber.

With this aspect of the invention, even if leak current occurs, the flow of power to the heater can be stopped while the heating furnace is within the discharge region.

With the heating furnace of this aspect of the invention, it is preferable if the controller switches off the power to the heater once the leak current detected by the leakage detector reaches a set current value that is at or below the permissible value, and switches on the power to the heater once the pressure inside the housing chamber as detected by the pressure detector reaches a set pressure value that is below the lower limit of the discharge region.

With this aspect of the invention, since the power to the heater is switched off once the leak current exceeds the maximum permissible value, and the power to the heater is switched on once the pressure inside the housing chamber reaches a set pressure value that is below the lower limit of the discharge region, the drying treatment can be continued. Therefore, the quality of the heating object can be stabilized.

With the heating furnace of this aspect of the invention, it is preferable if the controller switches off the power to the heater once the pressure inside the housing chamber as detected by the pressure detector reaches a first set value that is above the upper limit of the discharge region, and switches on the power to the heater once said pressure reaches a second set value that is below the lower limit of the discharge region.

With this aspect of the invention, since the power to the heater is switched off once the pressure inside the housing chamber reaches the first set value that is above the upper limit of the discharge region, and the power to the heater is switched on once the pressure reaches the second set value that is below the lower limit of the discharge region. Thus, the drying treatment can be continued, which means that the quality of the heating object can be stabilized. Furthermore, the upper limit for pressure and the lower limit for pressure may be determined ahead of time to facilitate management of the process.

Another aspect of the invention is also a method for drying a substrate to a specific region of which a functional liquid has been applied. The method includes reducing a pressure inside a housing chamber; heating a heating object in the housing chamber with a heater; switching off power to the heater once a leak current detection value, which is generated as the pressure inside the housing chamber is reduced while the power is supplied to the heater, reaches a set current value; and switching on the power to the heater once the pressure in the housing chamber is further reduced after the heater has been switched off, and the detected value of the pressure inside the housing chamber reaches a set pressure value.

With this aspect of the invention, there are a pressure reduction step of reducing the pressure in the housing chamber, a heating step of heating the heating object in the housing chamber with the heater, which is a step that at least partially overlaps and proceeds simultaneously with the pressure reduction step, a step of switching off the power to the heater once the leak current detection value, which is generated as the pressure inside the housing chamber is reduced while the power is supplied to the heater, reaches a set current value, and a step of switching on the power to the heater once the pressure is further reduced in the housing chamber after the heater has been switched off, and the detected value of the pressure inside the housing chamber reaches a set pressure value. The set current value and the set pressure value may be determined ahead of time, so management is simple.

Still another aspect of the invention is also a method for drying a substrate to a specific region of which a functional liquid has been applied. The method includes reducing a pressure inside a housing chamber; heating a heating object in the housing chamber with a heater; switching off power to the heater once the pressure in the housing chamber is reduced to a first set value while the power is supplied to the heater; and switching on the power to the heater once the pressure in the housing chamber is further reduced after the heater has been switched off, and the detected value of the pressure inside the housing chamber reaches a second set value.

With this aspect of the invention, there are a pressure reduction step of reducing the pressure in the housing chamber, a heating step of heating the heating object in the housing chamber with the heater, which is a step that at least partially overlaps and proceeds simultaneously with the pressure reduction step, a step of switching off power to the heater once the pressure in the housing chamber is reduced to a first set value while the power is supplied to the heater, and a step of switching on the power to the heater once the pressure in the housing chamber is further reduced after the heater has been switched off, and the detected value of the pressure inside the housing chamber reaches a second set value. The first set value for pressure and the second set value for pressure may be determined ahead of time, so management is simpler.

It is preferable if, in the step of switching off the power to the heater, the current value is 80 mA.

With this aspect of the invention, since the power to the heater can be switched off once the detected value for leak current in the housing chamber reaches 80 mA. Thus, there is no need to use a leak current blocker and shut down the apparatus.

It is preferable if, in the step of switching off the power to the heater, the pressure value is 1000 Pa.

With this aspect of the invention, since the power to the heater can be switched off once the detected value for pressure in the housing chamber reaches 1000 Pa. Therefore, the pressure value can be used in place of the leak current value, which makes this approach a simple one.

It is preferable if, in the step of switching on the power to the heater, the pressure value is 1 Pa.

With this aspect of the invention, since the power to the heater can be switched on once the detected value for pressure in the housing chamber reaches 1 Pa, the drying of the heating object can be continued. Thus, so quality of the heating object can be stabilized.

Still another aspect of the invention is also a method for manufacturing a device in which pixels are formed on a substrate by a droplet discharge method, wherein the above-mentioned drying method is used.

With this aspect of the invention, since the drying of the heating object can be continued, the quality of the heating object is stabilized. A method for manufacturing a device that yields stable quality can also be provided.

### BRIEF DESCRIPTION OF THE DRAWINGS

FIG. 1 is a simplified oblique view of the overall structure of a droplet discharge apparatus;

FIG. 2 is a partial oblique view that partially illustrates the main components of the droplet discharge apparatus;

FIG. 3 is a diagram of a head, with FIG. 3A being a simplified oblique view and FIG. 3B a diagram of the nozzle layout;

FIG. 4 is a diagram partially illustrating the main components of a head, with FIG. 4A being a simplified oblique view and FIG. 4B a simplified cross section;

FIG. 5 is a block diagram of the control system of the droplet discharge apparatus;

FIG. 6 is a simplified flowchart of the illustrating the operating procedure of a droplet discharge apparatus;

FIGS. 7A to 7H are cross sections of the steps of manufacturing an EL light emitting panel;

FIG. 8 is a simplified flowchart of the illustrating the procedure of the steps for manufacturing an EL light emitting panel;

FIGS. 9A to 9G are cross sections of the steps of manufacturing a color filter substrate;

FIG. 10 is a simplified flowchart of the illustrating the procedure of the steps for manufacturing a color filter substrate;

FIG. 11 consists of simplified diagrams of the overall structure of the drying apparatus used in the baking treatment, with FIG. 11A being a simplified plan view, and FIG. 11B a simplified cross section;

FIG. 12 is a block diagram of the control system of the drying apparatus;

FIG. 13 is a simplified flowchart of the procedure in operating the drying apparatus;

FIG. 14 is a timing chart for the drying apparatus;

FIG. 15 is a simplified flowchart of the procedure followed in the operation of the drying apparatus; and

FIG. 16 is a timing chart for the drying apparatus.

### DESCRIPTION OF EXEMPLARY EMBODIMENTS

The method for drying a heating object, the heating furnace, and the method for manufacturing a device of an aspect of the invention will now be described in detail through embodiments and through reference to the appended drawings. In this description, a substrate obtained by coating a base with a functional liquid by droplet discharge method is used as an example of the heating object. Before describing the characteristic constitution and method of this aspect the invention, first, the base used in the droplet discharge method, the droplet discharge method, the droplet discharge apparatus, and the structure of and method for manufacturing an EL light emitting panel will be described in order.

The base used in the method for manufacturing a display device by droplet discharge can be made of glass, quartz glass, plastic, or any of various other materials.

Droplet Discharge Method

Examples of the discharge technique involved in droplet discharge include electrostatic control, pressurized vibration, electromechanical conversion, electro-thermal conversion, and electrostatic attraction. Here, electrostatic control refers to imparting a charge to a material with a charging electrode, and discharging the material from a discharge nozzle while controlling the flight direction with a polarizing electrode. Pressurized vibration refers to applying a super-high pressure of about 30 kg/cm² to a material and thereby discharging the material from the tip of a nozzle. When no control voltage is applied, the material moves straight ahead and is discharged from the discharge nozzle, but if a control voltage is applied, electrostatic repulsion occurs between the material particles, and the material scatters and is not discharged from the discharge nozzle. Electro-mechanical conversion refers to utilizing the property of a piezo element to deform when subjected to a pulsed electrical signal. When the piezo element deforms, pressure is applied through a flexible substance to the space in which the material is contained, and the material is pushed out of this space and discharged from a discharge nozzle.

Electro-thermal conversion refers to generating bubbles by rapidly vaporizing a material with a heater provided in the space in which the material is contained, and discharging the material in this space with bubble pressure. Electrostatic attraction involves applying micropressure to the space in which a material is contained, forming a meniscus of material in a discharge nozzle, applying electrostatic force in this state, and then pulling out the material. In addition, it is also possible to apply a technique such as utilizing a change in the viscosity of a fluid produced by an electric field, or flinging out the material with a discharge spark. An advantage to a droplet discharge method is that there is no waste in the use of the material, and the desired amount of material can be accurately positioned where desired. The amount of one drop of liquid material discharged in a droplet discharge method is from 1 to 300 nanograms, for example.

Structure of Droplet Discharge Apparatus

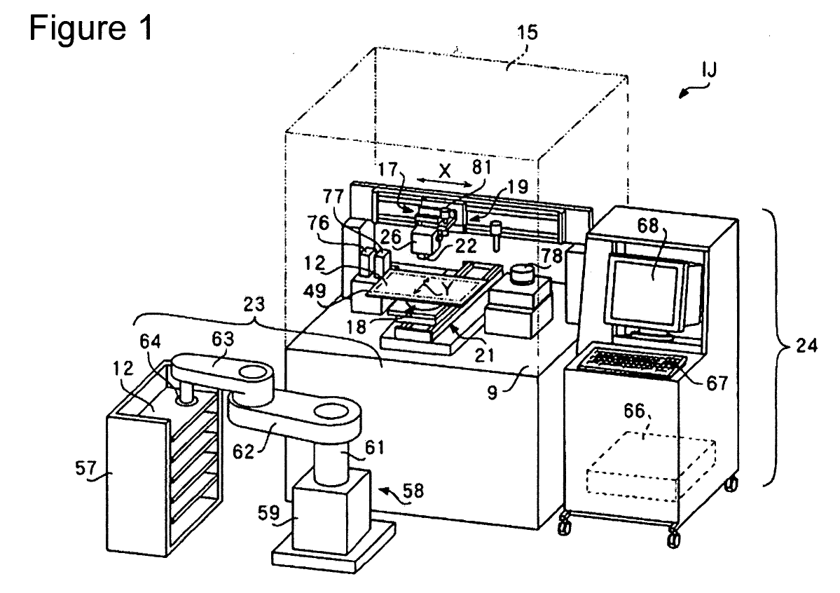

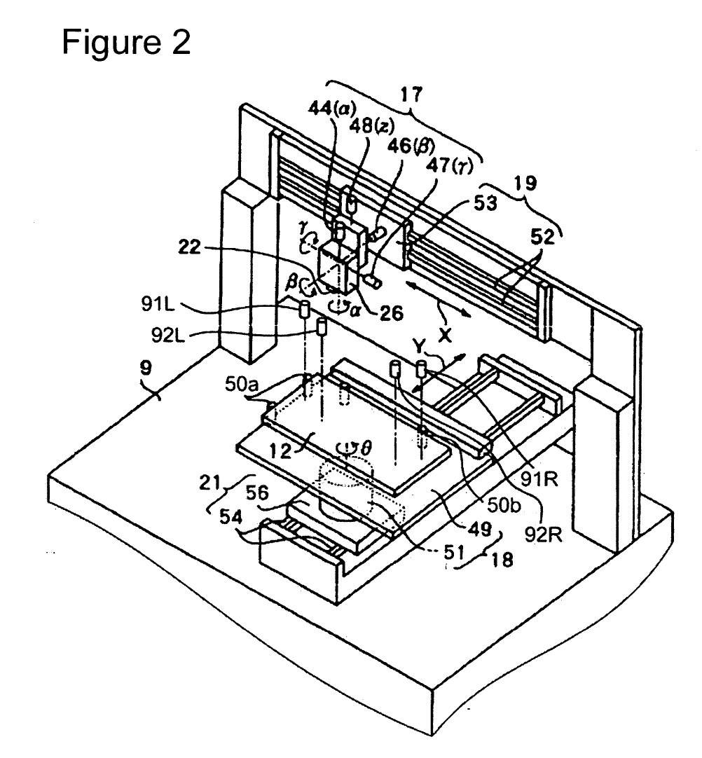

The structure of a droplet discharge apparatus will now be described. FIG. 1 is a simplified oblique view of the overall structure of a droplet discharge apparatus IJ, and FIG. 2 is a partial oblique view that partially illustrates the main components of the droplet discharge apparatus.

As shown in FIG. 1, the droplet discharge apparatus IJ has a head unit 26 equipped with a head 22 (an example of a droplet discharge head), a head position control unit 17 for controlling the position of the head 22, a substrate position control unit 18 for controlling the position of a substrate 12, a scanning drive unit 19 as a scanning drive means for scanning and moving the head 22 with respect to the substrate 12 in a scanning direction X, a feed drive unit 21 for moving the head 22 with respect to the substrate 12 in a Y direction that intersects (is perpendicular to) the scanning direction, a substrate supply unit 23 for supplying the substrate 12 to the required work position within the droplet discharge apparatus IJ, and a control unit 24 for performing general control of the droplet discharge apparatus IJ.

The head position control unit 17, the substrate position control unit 18, the scanning drive unit 19, and the feed drive unit 21 are installed on a base 9. These units are covered with a cover 15 as needed.

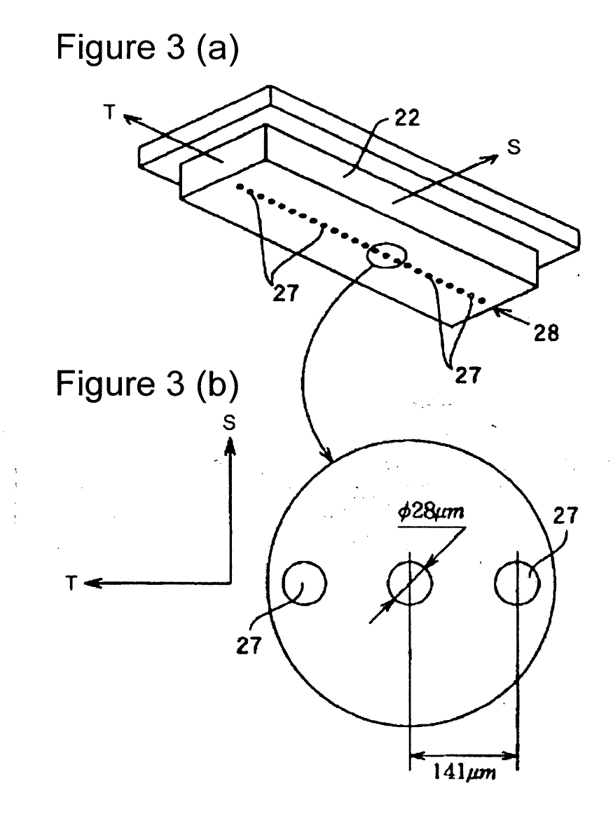

FIG. 3 is a diagram of a head, with FIG. 3A being a simplified oblique view and FIG. 3B a diagram of the nozzle layout. The head 22, as shown in FIG. 3A, for example, has a nozzle row 28 in which a plurality of nozzles 27 are arranged. The number of nozzles 27 is 180, for instance, the diameter of each nozzle 27 is 28 μm, for instance, and the pitch of the nozzles 27 is 141 μm, for instance (see FIG. 3B). The reference direction S shown in FIG. 3A indicates the standard scanning direction of the head 22, while the arrangement direction T indicates the direction in which the nozzles 27 are arranged in the nozzle row 28.

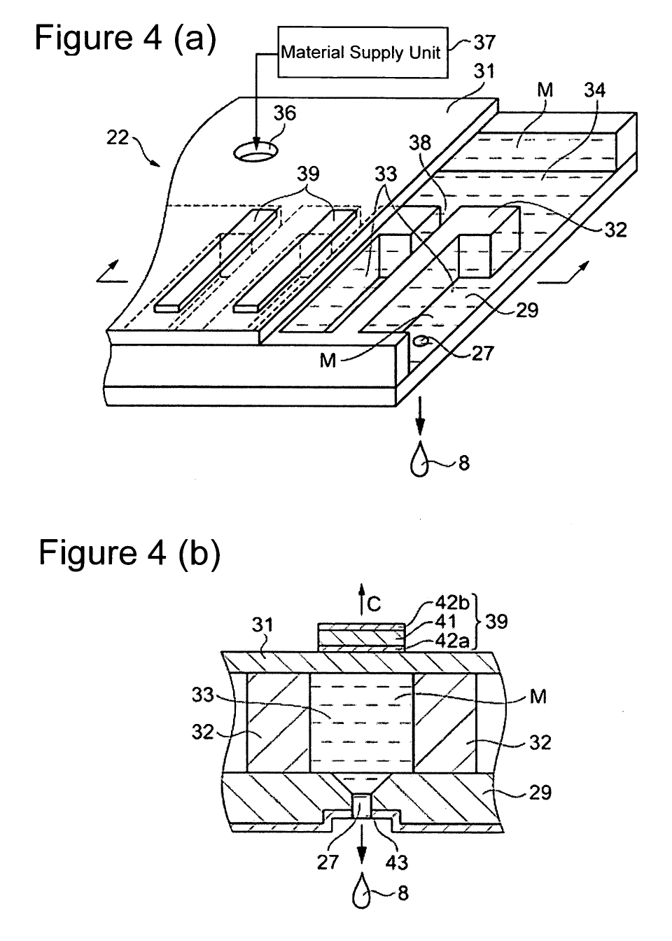

FIG. 4 shows the structure of the main components of a head, with FIG. 4A being a simplified oblique view and FIG. 4B a cross section. The head 22 has a nozzle plate 29 made of stainless steel or the like, a diaphragm 31 across from this plate, and a plurality of partition members 32 that join these two together. A plurality of liquid material chambers 33 and a reservoir 34 are formed by the partition members 32 between the nozzle plate 29 and the diaphragm 31. The liquid material chambers 33 and the reservoir 34 communicate with each other through channels 38.

A liquid supply hole 36is formed in the diaphragm 31. A liquid supply unit 37is connected to this liquid supply hole 36. The liquid supply unit 37 supplies a liquid material M, consisting of a red filter element material, for example, out of R, G, and B colors, to the liquid supply hole 36. The supplied liquid material M fills the reservoir 34, and then passes through the channels 38 to fill the liquid material chambers 33.

The nozzle plate 29 is provided with the nozzles 27 for spaying the liquid material M from the liquid material chambers 33 in the form of a jet. Liquid material pressing members 39 corresponding to the liquid material chambers 33 are attached on the back of the diaphragm 31, which is the side facing the liquid material chambers 33. As shown in FIG. 4B, these liquid material pressing members 39 each have a piezoelectric element 41 and a pair of electrodes 42a and 42b which flank the piezoelectric element 41 in between. The piezoelectric element 41 bends and deforms so as to protrude outward (as indicated by the arrow C) when power is supplied to the electrodes 42a and 42b, which increases the volume of the liquid material chamber 33. When this happens, the liquid material M, in an amount corresponding to the increase in volume, flows from the reservoir 34 through the channel 38 and into the liquid material chamber 33.

After this, when power to the piezoelectric element 41 is shut off, the piezoelectric element 41 and the diaphragm 31 both return to their original shapes, and as a result the liquid material chamber 33 also returns to its original volume, so the pressure of the liquid material M in the liquid material chamber 33 rises, and the liquid material M is sprayed out of the nozzle 27 as a droplet 8. In addition, a liquid repellent layer 43 composed of a nickel-tetrafluoroethylene eutectoid plated layer, for example, is provided around the nozzle 27 to prevent an arcing of the droplets 8, clogging of the nozzle 27, and so forth.

The head position control unit 17, substrate position control unit 18, scanning drive unit 19, feed drive unit 21, and other means disposed around the head 22 will now be described through reference to FIG. 2. As shown in FIG. 2, the head position control unit 17 has an alpha motor 44 for rotating the head 22 attached to the head unit 26 in a plane (horizontal plane), a beta motor 46 that oscillates the head 22 around an axis parallel to the feed direction Y, a gamma motor 47 that oscillates the head 22 around an axis parallel to the scanning direction X, and a Z motor 48 for moving the head 22 parallel to the vertical direction.

The substrate position control unit 18 has a table 49 on which a substrate 12 is placed, and a theta motor 51 that rotates the table 49 in a plane (horizontal plane). The scanning drive unit 19 has an X guide rail 52 extending in the scanning direction X, and an X slider 53 with a built-in pulse-driven linear motor, for example. When the built-in linear motor is operated, for example, the X slider 53 moves parallel to the scanning direction X along the guide rail 52.

The feed drive unit 21 has a Y guide rail 54 extending in the feed direction Y, and a Y slider 56 with a built-in a pulse-driven linear motor, for example. When the built-in linear motor is operated, for example, the Y slider 56 moves parallel to feed the sub-scanning direction Y along the guide rail 54.

The linear motors pulse-driven in the slider 53 and the slider 56 can precisely control the rotational angle of the output shaft by pulse signals supplied to the motors. Therefore, the position of the head 22 supported by the X slider 53 in the scanning direction X, the position of the table 49 in the feed direction Y, and the like can be precisely controlled. The positional control of the head 22 and the table 49 is not limited to the use of a pulse motor, and positional control can also be accomplished by feedback control using a servo motor, or any other method as desired.

Positioning pins 50a and 50b that restrict the planar position of the substrate 12 are provided to the table 49. The substrate 12 is held in position in a state in which the ends on the side in the scanning direction X and on the side in the feed direction Y are pressed in contact with the positioning pins 50a and 50b by a substrate supply unit 23. A known fixing means, such as air suction (vacuum chucking), is preferably provided for fixing the substrate 12 that is held in this positioned state.

As shown in FIG. 2, a plurality of sets (two sets in the depicted example) of imaging units 91R, 91L and 92R, 92L are disposed above the table 49 in the droplet discharge apparatus IJ. Here, only the body tubes of the imaging units 91R, 91L and 92R, 92L are shown in FIG. 2, and the other portions and the support structure thereof are not shown. A CCD camera or the like can be used as these imaging units (observation means). These imaging units are not shown in FIG. 1.

As shown in FIG. 1, the substrate supply unit 23 has a substrate housing component 57 that holds the substrate 12, and a robot or other such substrate movement mechanism 58 that transfers the substrate 12. The substrate movement mechanism 58 has a base 59, an elevating shaft 61 which moves up and down relative to the base 59, a first arm 62 that rotates around the elevating shaft 61, a second arm 63 that rotates relative to the first arm 62, and a suction pad 64 provided at the bottom of the distal end of the second arm 63. The suction pad 64 is designed so that the substrate 12 can be held in place by air suction (vacuum chucking) or the like.

A capping unit 76 and a cleaning unit 77 are disposed to one side of the feed drive unit 21 under the scanning path of the head 22. Also, an electronic balance 78 is disposed to the other side of the feed drive unit 21. The capping unit 76 serves to prevent the nozzles 27 (see FIG. 3) from drying out when the head 22 is in standby mode. The cleaning unit 77 serves to clean the head 22. The electronic balance 78 serves to weigh the droplets 8 of material discharged from each of the nozzles 27 of the head 22. A head camera 81 that moves integrally with the head 22 is attached near the head 22.

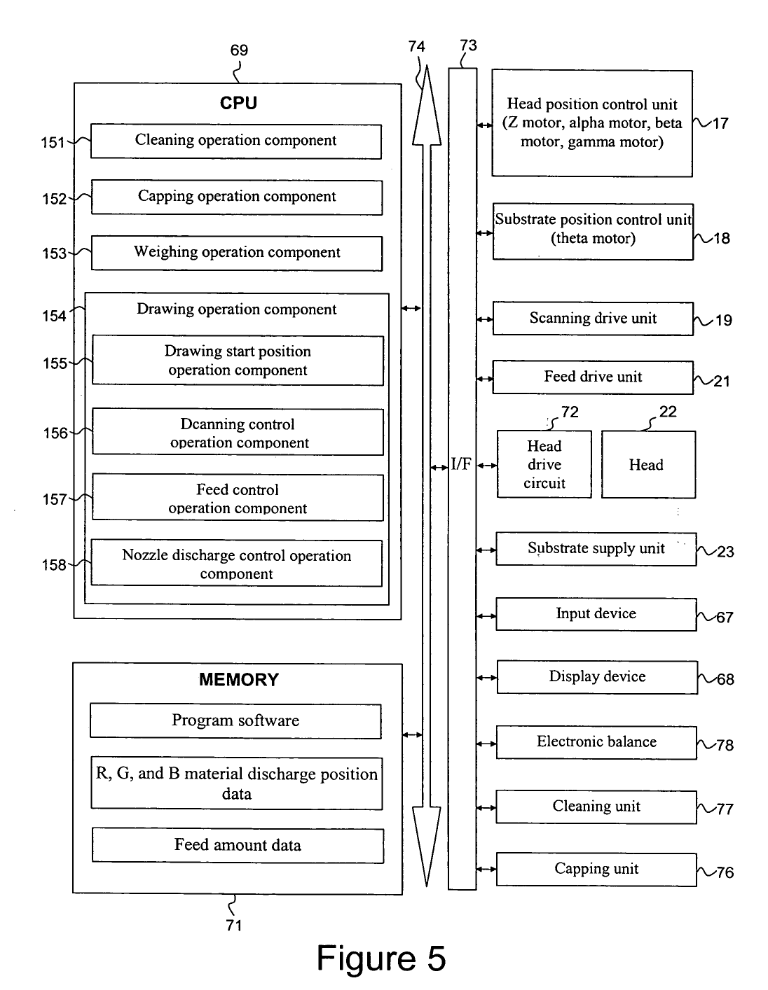

The control unit 24 has computer 66 containing a processor, a keyboard or other such input unit 67, and a CRT or other such display unit 68. The computer 66 is equipped with a CPU (Central Processing Unit) 69 and an information storage medium 71 that is a memory that stores various kinds of information, as shown in FIG. 5.

FIG. 5 is a block diagram of the control system of the droplet discharge apparatus IJ. The head position control unit 17, the substrate position control unit 18, the scanning drive unit 19, the feed drive unit 21, and a head drive circuit 72 that drives the piezoelectric elements 41 (see FIG. 4B) in the head 22 are connected to the CPU 69 through an input/output interface 73 and a bus 74, as shown in FIG. 5. The substrate supply unit 23, the input unit 67, the display unit 68, the capping unit 76, the cleaning unit 77, and the electronic balance 78 are also connected to the CPU 69 through the input/output interface 73 and the bus 74. The memory 71 is a concept encompassing semiconductor memory such as RAM (Random Access Memory) or ROM (Read Only Memory); external storage units that read data using disk-type storage medium such as a hard disk, a CD-ROM (Compact Disk Read Only Memory), a DVD (Digital Versatile Disk), MD (Mini Disk), or the like; and so forth. Functionally, various kinds of storage area are set up, such as a storage area for storing program software in which the control procedure for operation of the liquid droplet discharge apparatus IJ are written, a storage area for storing as coordinate data the positions within the substrate 12 where material is discharged by the head 22, a storage area for storing the amount of movement of the substrate 12 in the feed direction Y shown in FIG. 2, and areas functioning as a work area or a temporary file for the CPU 69.

The CPU 69 controls the discharge of material at specific positions on the surface of the substrate 12 according to the program software stored in the memory (the information storage medium 71). Specific function implementation components of the CPU 69 include a cleaning operation component 151 that performs an operation for implementing a cleaning treatment, a capping operation component 152 that implements a capping treatment, a weighing operation component 153 that performs an operation for implementing weighing with the electronic balance 78, and a drawing operation component 154 for drawing a specific pattern by causing the material to land on the surface of the substrate 12 by droplet discharge.

The drawing operation component 154 has various functional operation components, such as a drawing start position operation component 155 for putting the head 22 at its initial position for drawing, a scanning control operation component 156 that computes control for scanning and moving the head 22 in the scanning direction X at a specific speed, a feed control operation component 157 that computes control for shifting the substrate 12 in the feed direction Y by a specific amount of feed movement, and a nozzle discharge control operation component 158 that performs computation for controlling which nozzle of the plurality of nozzles in the head 22 are to be operated to discharge the material.

Each of the above functions is implemented by program software using the CPU 69, but if the functions can be implemented by an electronic circuit without using a CPU, then such an electronic circuit may be used.

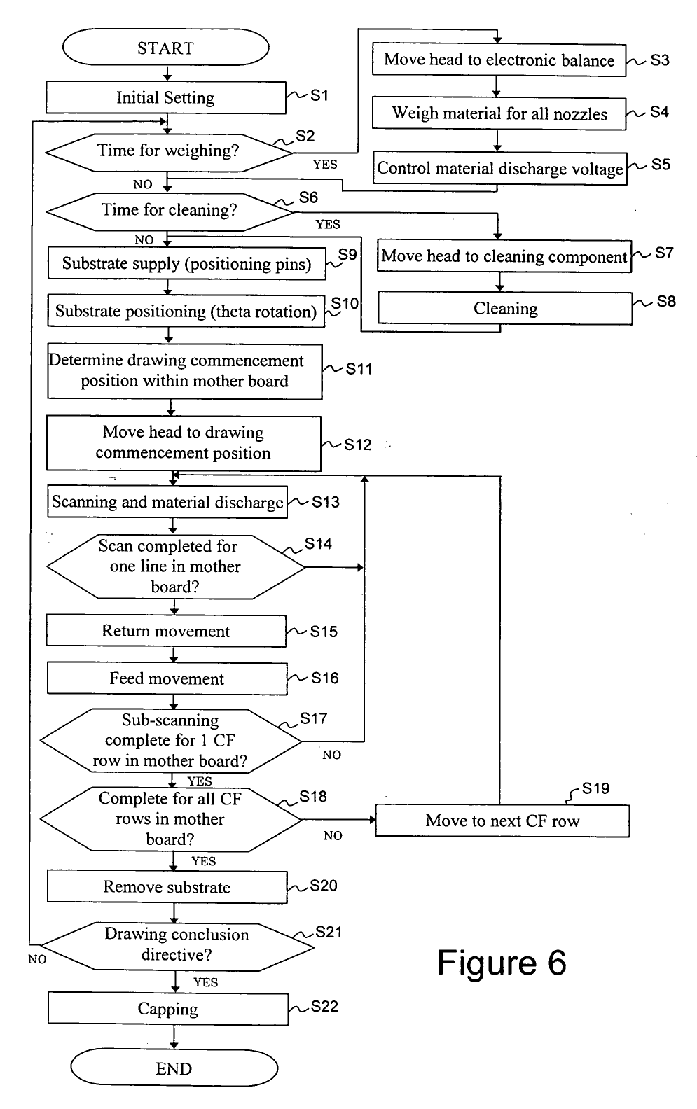

The operation of the droplet discharge apparatus IJ will now be described on the basis of the flowchart shown in FIG. 6. When an operator turns on a power supply to start the droplet discharge apparatus IJ, an initial setting is first made (step S1). More specifically, the head unit 26, the substrate supply unit 23, the control unit 24, and the like are set in a predetermined initial state.

Next, when it is time for weighing (step S2), the head unit 26 shown in FIG. 2 is moved to the electronic balance 78 shown in FIG. 1 by the scanning drive unit 19 (step S3). The amount of liquid material discharged from each of the nozzles 27 is then measured by using the electronic balance 78 (step S4). Further, the voltage applied to the piezoelectric element 41 of each of the nozzles 27 is adjusted according to the liquid material discharge characteristics of the nozzles 27 as measured above (step S5).

After this, when it is time for cleaning (step S6), the head unit 26 is moved to the cleaning unit 77 by the scanning drive unit 19 (step S7), and the head 22 is cleaned by the cleaning unit 77 (step S8).

When it is not yet time for weighing or cleaning, or when weighing and cleaning have already been completed, the substrate supply unit 23 shown in FIG. 1 is operated to supply the substrate 12 to the table 49 in step S9. More specifically, the substrate 12 is held in the substrate housing component 57 by the suction pad 64, the elevating shaft 61, the first arm 62, and the second arm 63 are moved to transfer the substrate 12 to the table 49, and the substrate 12 is pressed onto the positioning pins 50a and 50b (see FIG. 2) that have been set up at suitable positions on the table 49.

Next, as shown in FIG. 2, the output shaft of the theta motor 51 is rotated in tiny angular units to rotate the table 49 in a plane (the horizontal plane) and position the substrate 12 while the substrate 12 is observed with the imaging units 91R and 91L (step S10). More specifically, alignment marks formed on the left and right sides of the substrate 12 are imaged with the above-mentioned pairs of imaging units 91R and 91L or 92R and 92L shown in FIG. 2, the planar orientation of the substrate 12 is computed from the imaged positions of these alignment marks, and the table 49 is rotated and the angle θ adjusted according to this planar orientation.

After this, the position where drawing by the head 22 is to be started is determined by computation while the substrate 12 is observed with the head camera 81 shown in FIG. 1 (step S11). The scanning drive unit 19 and the feed drive unit 21 are then appropriately operated to move the head 22 to the drawing start position (step S12).

Here, the head 22 may be oriented such that the reference direction S shown in FIG. 3 coincides with the scanning direction X, or such that the reference direction S is inclined at a specific angle to the scanning direction. The pitch of the nozzles 27 is generally different from the pitch of the positions on the surface of the substrate 12 where the material is supposed to land, so this specific angle is a way to ensure that the dimensional component in the feed direction Y of the pitch of the nozzles 27 arranged in the arrangement direction T will geometrically match the pitch of the landing positions on the substrate 12 in the feed direction Y when the head 22 is moved in the scanning direction X.

When the head 22 is put in the drawing start position in step S12 shown in FIG. 6, the head 22 is scanned linearly at a constant velocity in the scanning direction X (step S13). During this scanning, droplets of ink are continuously discharged from the nozzles 27 of the head 22 onto the surface of the substrate 12.

The amount in which the ink droplets are discharged may be set so that the total amount is discharged over the discharge range that can be covered by the head 22 in a single scan, but the configuration may instead be such that only a fraction (such as one-fourth) of the amount of material that would otherwise be discharged in a single scan is discharged, or, when the head 22 is scanned a plurality of times, the configuration may be such that each scanning range is set to partially overlap the previous one, and the material is discharged a number of times (such as four times) over the entire region.

When the head 22 has completed scanning for one line on the substrate 12 (step S14), it moves backward and returns to its initial position (step S15), and moves by a specific amount (the set feed amount) in the feed direction Y (step S16). Each time, the head 22 is again scanned in step S13 and material is discharged, and thereafter the above operation is repeated so that scanning is performed over a plurality of lines. Once the scanning for one line has been completed, the head 22 may also be driven such that it continues moving by a specific amount in the feed direction Y, then turns around and scans back in the opposite direction, so that the scanning direction is alternately reversed.

The formation of a plurality of color filters in the substrate 12 will now be described. When the discharge of all the material has been completed for one row of color filter region in the substrate 12 (step S17), then the head 22 moves by a specific amount in the feed direction Y and the operations of steps S13 to S16 are repeated the same as above. When the discharge of material into the color filter regions of all the rows on the substrate 12 is finally concluded (step S18), the treated substrate 12 is sent to the outside by the substrate supply unit 23 or another transfer mechanism in step S20. After this, the supply of a substrate 12 and the discharge of material are repeated just as above, unless the process termination is directed by the operator. If all rows of color filter have been completed in step S18, the head 22 moves to the color filter region of the next row (step S19), and the operations from steps S13 to S18 are repeated.

When the completion of work is directed by the operator (step S21), the CPU 69 transfers the head 22, shown in FIG. 1, to the capping unit 76, and the capping unit 76 caps the head 22 (step S22).

The droplet discharge apparatus described above can be used in the arrangement method and manufacturing method pertaining to the embodiment of the invention, but the invention is not limited to this, and any kind of apparatus can be used as long as it is capable of discharging droplets and causing them to land at predetermined landing sites.

In the embodiment of the invention, the droplet discharge head, such as the head of the above-mentioned droplet discharge apparatus, is preferably scanned in the lengthwise direction of the above-mentioned region (for instance, if a substantially rectangular region or opening, the direction in which the long side thereof extends, and if a substantially band-shaped region or opening, the direction in which this band extends).

Structure of and Method for Manufacturing EL Light Emitting Panel

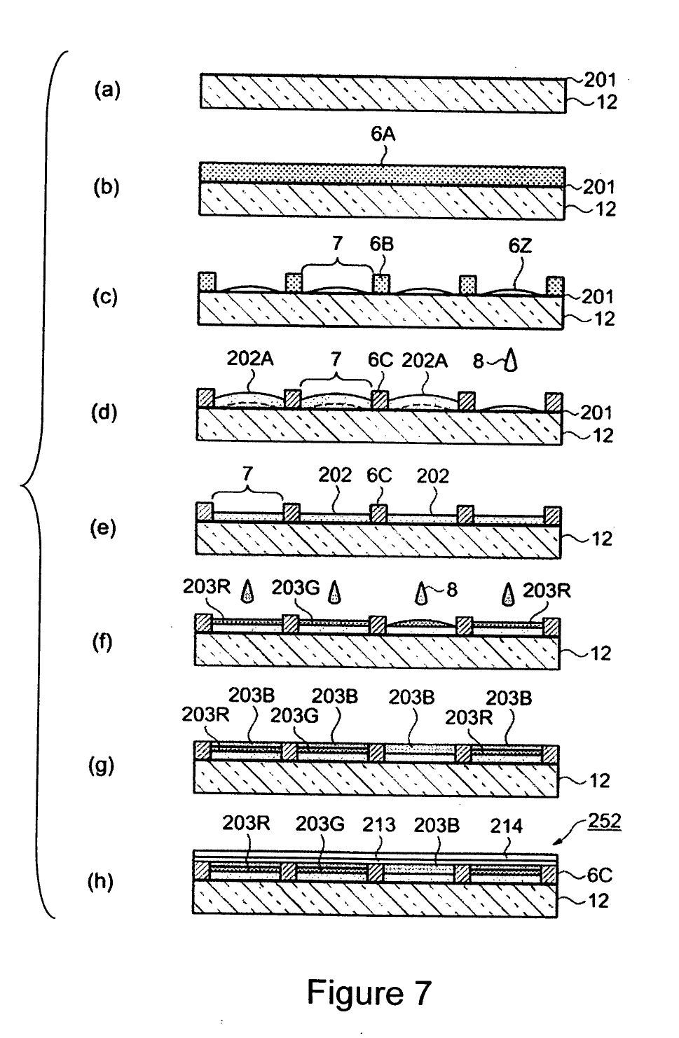

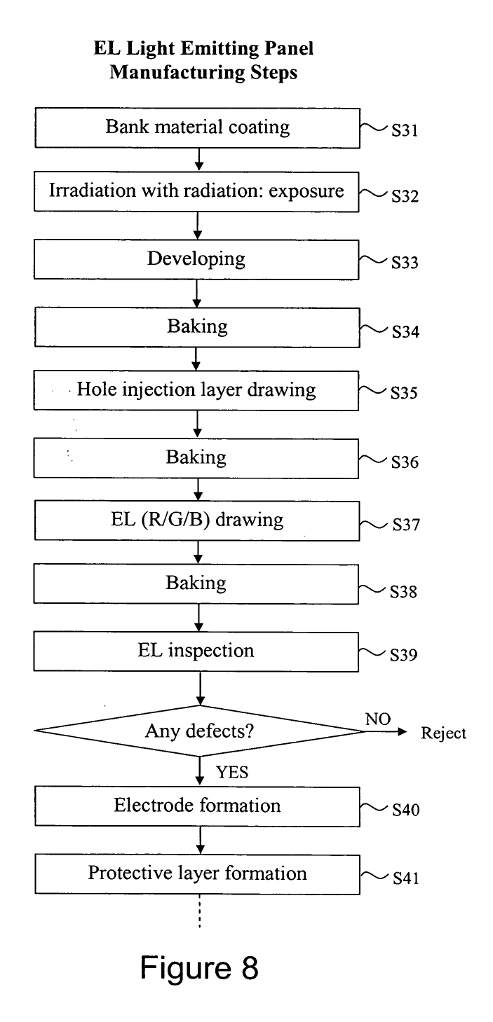

Next, an EL light emitting panel 252 and the method for manufacturing this panel will be described through reference to FIGS. 7 and 8. FIGS. 7A to 7H here are cross sections of the steps of manufacturing the EL light emitting panel 252, and FIG. 8 is a simplified flowchart illustrating the procedure of the steps for manufacturing the EL light emitting panel 252.

As shown in FIG. 7A, when the EL light emitting panel 252 is manufactured, a first electrode 201 is formed on the substrate 12, which is made of translucent glass, plastic, or the like. If the EL light emitting panel 252 is passive matrix type, the first electrode 201 is formed in the shape of a band, but when it is an active matrix type, in which active elements such as TFD elements or TFT elements (not shown) are formed on the substrate 12, the first electrode 201 is formed independently for every display dot. These structures can be formed by photolithography, vacuum vapor deposition, sputtering, pyrosol method, or the like. The material of the first electrode 201 can be ITO (Indium Tin Oxide), tin oxide, a compound oxide of indium oxide and zinc oxide, or the like.

Next, as shown in FIG. 7B, the first electrode 201 is coated with a radiosensitive material 6A (positive type) by the same method as with the above-mentioned color filter substrate (step S31 in FIG. 8). Then, as shown in FIG. 7C, radioactive irradiation (exposure) (step S32 in FIG. 8) and developing (step S33 in FIG. 8) are performed by the same methods as above to form a barrier (bank) 6B.

This bank 6B is formed in the shape of a lattice, and so as to separate the first electrodes 201 formed for each display dot, that is, so as to constitute EL light emitting component formation regions 7 corresponding to the display dots. Also, just as with the color filter substrate above, it is preferable if this bank 6B also has a light blocking function. In this case, contrast is enhanced, color mixing of the light emitting materials is prevented, and the leakage of light between pixels is prevented, for example. The material of the bank 6B can basically be the various kinds of material employed for the barrier of the above-mentioned color filter substrate. In this case, however, it is particularly favorable for the material to be resistant to the solvent of the EL light emitting material (discussed below), and it is preferable if the material can be tetrafluoroethylenated by a fluorocarbon gas plasma treatment. Examples of this include organic materials such as acrylic resins, epoxy resins, and photosensitive polyimides.

Next, the substrate 12 is subjected to a continuous plasma treatment with an oxygen gas and fluorocarbon gas plasma immediately before being coated with a hole injection layer material 202A (serving as a functional liquid). As a result, the polyimide surface is rendered water repellent, the ITO surface is rendered hydrophilic, and the wettability of the substrate side can be controlled for finely patterning the droplets. The apparatus that generates the plasma can be one that generates a plasma in a vacuum, or one that generates a plasma in the atmosphere, both of which can be used equally well. Apart from this process, or instead of this process, the barrier 6B is baked at about 200° C. (step S34 in FIG. 8). This forms a barrier 6C.

Next, as shown in FIG. 7D, the hole injection layer material 202A is discharged in the form of the droplets 8 and made to land in the regions 7 (step S35 in FIG. 8). This hole injection layer material 202A is the product of using a solvent or the like to liquefy the material used for the hole injection layer.

Next, as shown in FIG. 7E, this product is baked in a vacuum (1 to 0.01 Pa) for 15 minutes at 60° C. to form a hole injection layer 202 (step S in FIG. 8). Under the above conditions, the thickness of the hole injection layer 202 was 40 nm.

Next, as shown in FIG. 7F, a R light emitting layer material, a G light emitting layer material, and a B light emitting layer material (used as the EL light emitting materials that are functional liquids) were introduced as droplets in the same manner as above over the hole injection layer 202 within the regions 7 (step S37 in FIG. 8). The coatings of these light emitting layer materials were baked in a vacuum (1 to 0.01 Pa) for 50 minutes at 60° C. to remove the solvent and form a red light emitting layer 203R, a green light emitting layer 203G, and a blue light emitting layer 203B (step S38 in FIG. 8). Light emitting layers formed by heat treatment are insoluble in solvents. The thickness of the red light emitting layer 203R, the green light emitting layer 203G, and the blue light emitting layer 203B formed under the above conditions was 50 nm.

The hole injection layer 202 may be subjected to a continuous plasma treatment with an oxygen gas and fluorocarbon gas plasma prior to the formation of the light emitting layers. This will form a fluoride layer over the hole injection layer 202, the hole injection efficiency will be increased by the higher ionization potential, and an organic EL device with higher light emission efficiency can be provided.

As shown in FIG. 7G, if the blue light emitting layer 203B is disposed overlapping, then not only will the three primary colors of R, G, and B be formed, but the steps between the red light emitting layer 203R, the green light emitting layer 203G, and the blue light emitting layer 203B will be buried and smoothed over. This effectively prevents shorting between upper and lower electrodes. Meanwhile, if the thickness of the blue light emitting layer 203B is adjusted, then the blue light emitting layer 203B will act as an electron injection transport layer in the laminar structure of the red light emitting layer 203R and the green light emitting layer 203G, and will not emit blue light. The blue light emitting layer 203B can be formed by a standard spin coating method as a wet process, for example, or the same method as that used for forming the red light emitting layer 203R and the green light emitting layer 203G can be employed.

The red light emitting layer 203R, the green light emitting layer 203G, and the blue light emitting layer 203B can be arranged in a known pattern, such as a stripe arrangement, delta arrangement, or mosaic arrangement, according to the required display performance.

Next, The EL light emitting panel 252 in which the hole injection layer 202 and the red light emitting layer 203R, green light emitting layer 203G, or blue light emitting layer 203B have been formed for each display dot is inspected by visual observation or with a microscope or the like, or by imaging or other such processing (step S39 in FIG. 8). The panel is rejected from the process if this inspection reveals defects (missing dots, defective laminar structure, too much material in the light emitting components, admixture of dust or other impurities, and so forth) in the EL light emitting components (having a laminate of the hole injection layer 202 and the red light emitting layer 203R, green light emitting layer 203G, or blue light emitting layer 203B) in each display dot.

As shown in FIG. 7H, if this inspection reveals no defects, a counter electrode 213 is formed (step S40 in FIG. 8). If the counter electrode 213 is formed as a planar electrode, it can be formed by a deposition method, sputtering, or another such film formation method using, for example, magnesium, silver, aluminum, lithium, or the like as the material. When the counter electrodes 213 are formed as stripe electrodes, they can be formed by patterning a formed electrode layer by photolithography or another such method. Finally, as shown in FIG. 7H, a protective layer 214 is formed from a suitable material (such as a resin molded material or an inorganic insulating film) over the counter electrode 213 (step S41 in FIG. 8), which completes the manufacture of the targeted EL light emitting panel 252.

Structure of and Method for Manufacturing a Color Filter Substrate

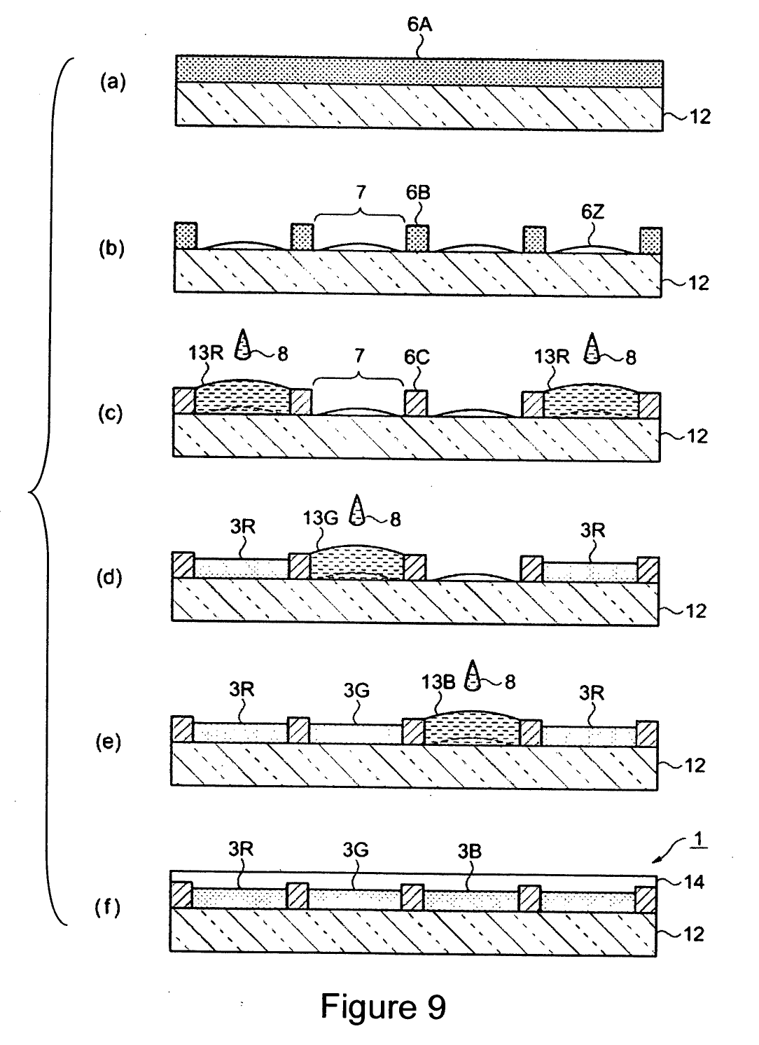

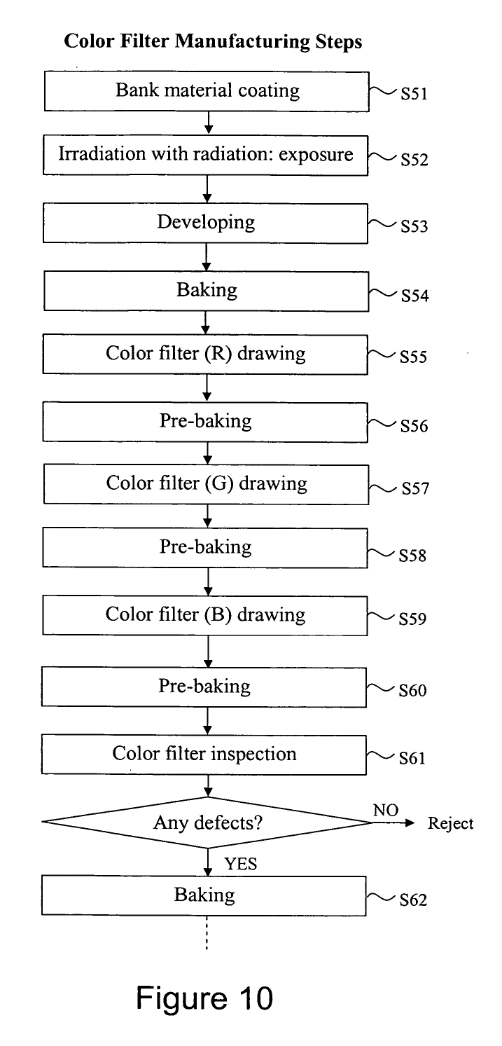

FIGS. 9A to 9F are cross sections of the steps of manufacturing a color filter substrate. FIG. 10 is a simplified flowchart illustrating the procedure of the steps for manufacturing the color filter substrate.

As shown in FIG. 9A, the surface of the substrate 12, which is made of translucent glass, plastic, or the like, is coated with the radiosensitive material 6A by any of various methods, such as spin coating, flow coating, or roll coating (step S51 in FIG. 10). This radiosensitive material 6A is preferably a resin composition. The thickness of the radiosensitive material 6A after coating is usually from 0.1 to 10 μm, and preferably 0.5 to 3.0 μm.

This resin composition can be, for instance, (i) a radiosensitive resin composition that is cured by irradiation with radiation, containing a binder resin, a polyfunctional monomer, a photopolymerization initiator, or the like, or (ii) a radiosensitive resin composition that is cured by irradiation with radiation, containing a binder resin, a compound that generates an acid upon irradiation with radiation, a crosslinkable compound that can be crosslinked by the action of an acid generated by irradiation with radiation, or the like. These resin compositions are usually prepared as liquid compositions by mixing with a solvent at the time of use, and this solvent may be one with either a high or a low boiling point. The radiosensitive material 6A is preferably a composition such as that described in JP-A-H10-86456, containing (a) a copolymer of hexafluoropropylene, an unsaturated carboxylic acid (anhydride), and another copolymerizable ethylenic unsaturated monomer, (b) a compound that generates an acid upon irradiation with radiation, (c) a crosslinkable compound that can be crosslinked by the action of an acid generated by irradiation with radiation, (d) a fluorine-containing organic compound other than component (a), and (e) a solvent capable of dissolving the components (a) to (d).

Next, the radiosensitive material 6A is irradiated with (exposed to) radiation through a mask with a specific pattern (step S52 in FIG. 10). The term “radiation” includes visible light, ultraviolet rays, X-rays, electron beams, and so forth, but radiation (light) with a wavelength between 190 and 450 nm is preferable.

Next, the radiosensitive material 6A is developed (step S53 in FIG. 10), which forms the barrier (bank) 6B shown in FIG. 9B. This barrier 6B is formed in a shape corresponding to the above-mentioned pattern mask (negative pattern). The shape of the barrier 6B is preferably that of a lattice that allows the rectangular filter element formation regions 7 to be arranged longitudinally and laterally within a plane. An alkaline developing solution is used to develop the radiosensitive material 6A. This alkaline developing solution is preferably an aqueous solution of sodium carbonate, sodium hydroxide, potassium hydroxide, sodium silicate, sodium metasilic ate, aqueous ammonia, ethyl amine, n-prop yl amine, diethylamine, di-n-propylamine, triethylamine, methyldiethylamine, dimethylethanolamine, triethanolamine, tetramethylammonium hydroxide, choline, pyrrole, piperidine, 1,8-diazabicyclo[5,4,0]-7-undecene, 1,5-diazabicyclo[4,3,0]-5-nonene, or the like. Methanol, ethanol, or another such water-soluble organic solvent, a surfactant, or the like can also be added in a suitable amount to this alkaline developing solution. After developing with an alkaline developing solution; the product is usually rinsed with water.

Next, as shown in FIG. 9C, the barrier 6B is baked at about 200° C. to form the barrier 6C (step S54 in FIG. 10). The baking temperature here is suitably adjusted according to the radiosensitive material 6A. It is conceivable that no baking will be necessary in some cases. In this embodiment, the barrier 6C functions both as a literal barrier that demarcates (delineates) the regions 7, and as a light blocking layer that shields portions other than the regions 7. The barrier 6C may, of course, be designed so that it only functions as a barrier. In this case, a light blocking layer made of a metal or the like may be formed separately in addition to the barrier.

Next, filter element materials 13 (in the example in FIG. 9, 13R (red colorant), 13G (green colorant), and 13B (blue colorant)) produced by mixing a colorant (pigment, dye, etc.) into a base material such as an acrylic resin are introduced into the various regions 7 demarcated by the barrier 6C formed as above. The filter element materials 13 are introduced into the regions 7 by the following method. The filter element materials 13 are formed as liquid materials (functional liquids) by mixing with a solvent or the like, and these functional liquids are introduced into the regions 7. More specifically, in this embodiment, the materials are introduced by causing the functional liquids to land in the form of droplets 8 in the regions 7 by droplet discharge using a droplet discharge head (discussed below).

After the filter element materials 13 have been introduced as functional liquids into the regions 7, either drying is performed or pre-baking is performed by baking at a low temperature (such as 60° C.), which pre-solidifies or pre-cures the liquids. For example, after the filter element material 13R has been introduced (step S55 in FIGS. 9c and 10), the filter element material 13R is pre-baked to form a filter element 3R (step S56 in FIG. 10), and then the filter element material 13G is introduced (step S57 in FIGS. 9D and 10) and the filter element material 13G is pre-baked to form a filter element 3G (step S58 in FIG. 10), and the filter element material 13B is then introduced (step S59 in FIGS. 9E and 10) and the filter element material 13B is pre-baked to form a filter element 3B (step S60 in FIGS. 9F and 10). Thus introducing the filter element materials 13 of all colors into the regions 7, and forming filter elements 3 (3R, 3G, and 3B), which are pre-solidified or pre-cured display elements, forms a display material (color filter substrate CF).

The color filter substrate CF (display material) constituted as above is then inspected (step S61 in FIG. 10). This inspection involves observing the filter elements 3 (the display elements) and the barrier 6C either visually or with a microscope or the like. The color filter substrate CF may also be imaged and the inspection performed automatically on the basis of the resulting image. If this inspection reveals any defects in the filter elements 3 (display elements), that color filter substrate CF is rejected and sent to a base recycling step.

Defects in the filter elements 3 here include when a filter element 3 is missing (known as a missing dot), or when a filter element 3 has been formed, but the amount (volume) of material disposed in the region 7 is either too much or too little, or when a filter element 3 has been formed, but dust or other foreign matter is admixed or adheres, for example.

If the inspection turns up no defects in the display materials, baking is performed at a temperature of about 200° C., for example, to completely solidify or cure the filter elements 3 (3R, 3G, and 3B) of the color filter substrate CF (step S62 in FIG. 10). The product is rejected if any defects are found. The baking temperature here is suitably determined according to the composition of the filter element material 13 and other such factors. There is no particular need to heat to a high temperature, and this need only involve drying or aging in an atmosphere that is out of the ordinary (such as in nitrogen gas or in dry air). Finally, as shown in FIG. 9F, a transparent protective layer 14 is formed over the filter elements 3.

### First Embodiment

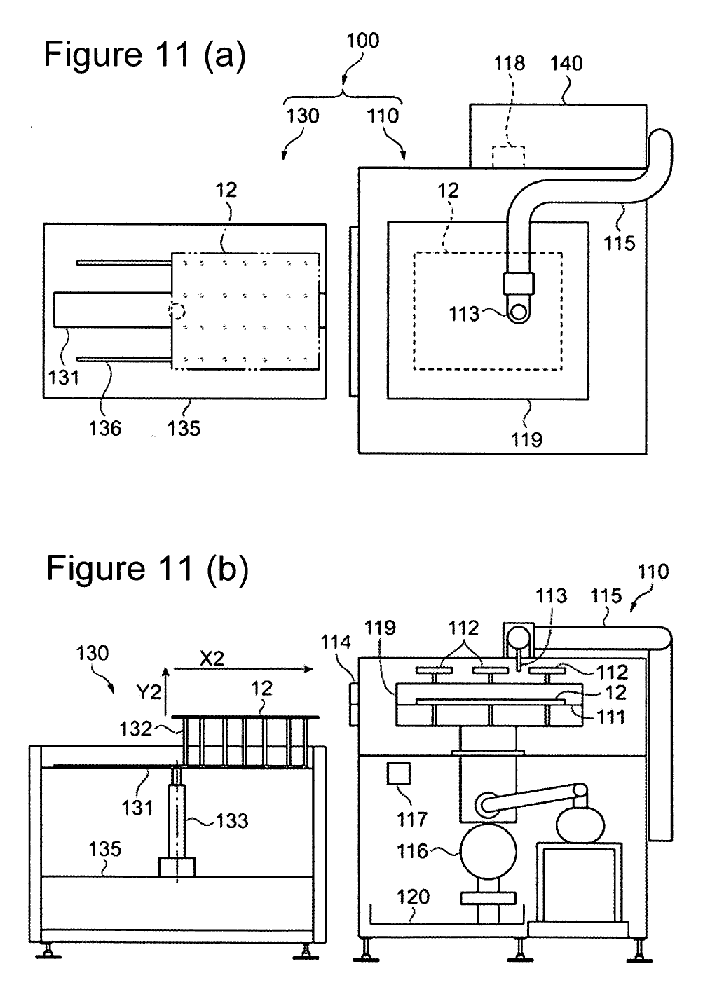

The main components related to the baking treatment of this embodiment of the invention that can be applied in the course of manufacturing the color filter substrate and the EL light emitting panel described above will now be described. FIG. 11 consists of simplified diagrams of the overall structure of the drying apparatus used in the baking treatment. FIG. 11A is a simplified plan view, and FIG. 11B is a simplified cross section. The applicable baking treatment steps of the embodiment of the invention are steps S36 and S38 in the process of manufacturing an EL light emitting panel in FIG. 8. Similarly, the applicable steps are steps S56, S58, and S60 in the process of manufacturing a color filter in FIG. 10.

As shown in FIGS. 11A and 11B, a drying apparatus 100 includes a heating component 110 (used as a heating furnace) having a heater 112, a substrate supply unit 130 capable of transporting the substrate 12, and a control panel 140 for operating the drying apparatus 100. The substrate supply unit 130 has a pneumatic cylinder 133 for moving the substrate 12 up and down (Y2 direction), and a pneumatic cylinder (not shown) for putting the substrate 12 in a housing chamber 119 provided to the heating component 110. A linear guide 136 is provided to allow the substrate 12 to slide in the X2 direction.

A table 131 and shafts 132 on which the substrate 12 is disposed are connected in the substrate supply unit 130. The pneumatic cylinder 133 is engaged with the table 131, and fixed on a frame 135.

When a door 114 of the heating component 110 is opened, the substrate 12 that has been brought from the substrate supply unit 130 can be housed in the housing chamber 119. A holder 111 on which the substrate 12 is placed is disposed inside the housing chamber 119. A plurality of the heaters 112 are disposed over the substrate 12 in the housing chamber 119. When these heaters 112 are switched on, the substrate 12 and the interior of the housing chamber 119 are heated. A thermocouple 113 for monitoring the temperature inside the housing chamber 119 is disposed near the heaters 112.

A vacuum pump 116 is used to lower the pressure inside the housing chamber 119 from atmospheric pressure in order to ensure a vacuum within the housing chamber 119. This vacuum pump 116 is disposed over a frame 120. When this vacuum pump 116 is operated, any gas present in the housing chamber 119 is exhausted to the outside of the drying apparatus 100. The operation of the vacuum pump 116 also reduces the pressure inside the housing chamber 119. An exhaust duct 115 for exhausting this gas is connected to the vacuum pump 116 and fixed to the frame 120 by a method that is not depicted in the drawings.

A pressure sensor 117 for checking the degree of vacuum in the housing chamber 119 is fixed to the frame 120 by a method that is not depicted in the drawings. A leakage detection unit 118 for detecting leak current within the housing chamber 119 is fixed inside the control panel 140 by a method that is not depicted in the drawings. The drying apparatus 100 is also configured such that the control panel 140 used for operating this drying apparatus 100 (shown in FIG. 11A) is fixed to the frame 120 by a method that is not depicted in the drawings.

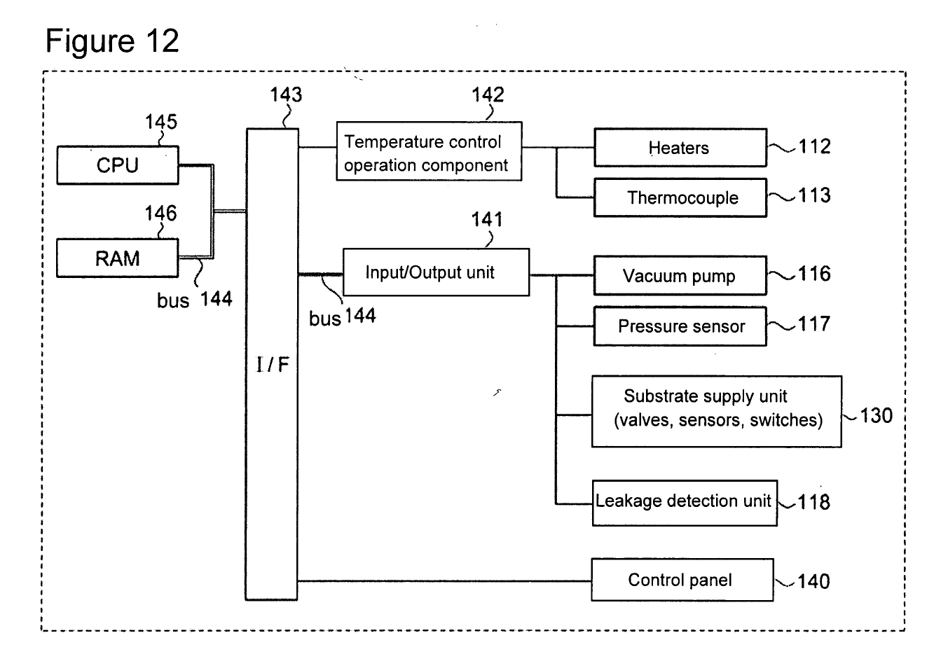

FIG. 12 is a block diagram of the control system of the drying apparatus 100. As shown in FIG. 12, the control panel 140, an input/output unit 141, and a temperature control operation component 142 are connected to a CPU 145 and a RAM 146 via an input/output interface 143 and a bus 144. The vacuum pump 116, the pressure sensor 117, the substrate supply unit 130, and the leakage detection unit 118 are connected to the input/output unit 141. The heaters 112 and the thermocouple 113 are connected to the temperature control operation component 142. The input/output unit 141 is made up of a drive circuit, an A/D converter, or the like, and can input the values detected by the pressure sensor 117 and the leakage detection unit 118 to the input/output unit 141. The output from the input/output unit 141 drives the vacuum pump 116 and the substrate supply unit 130. This unit also operates switches and so forth for operating the valves, sensors, and pneumatic cylinders in the substrate supply unit 130.

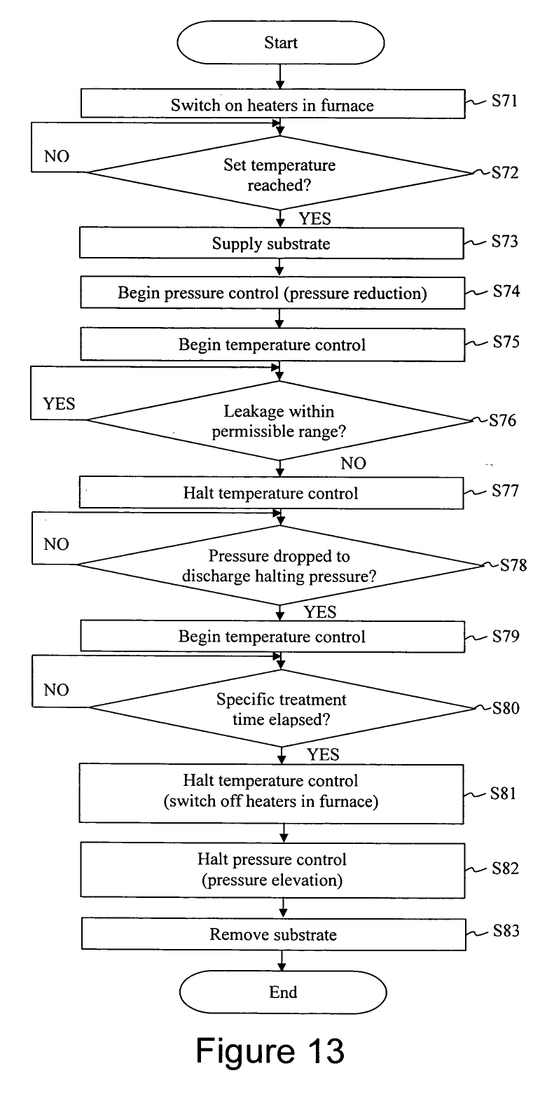

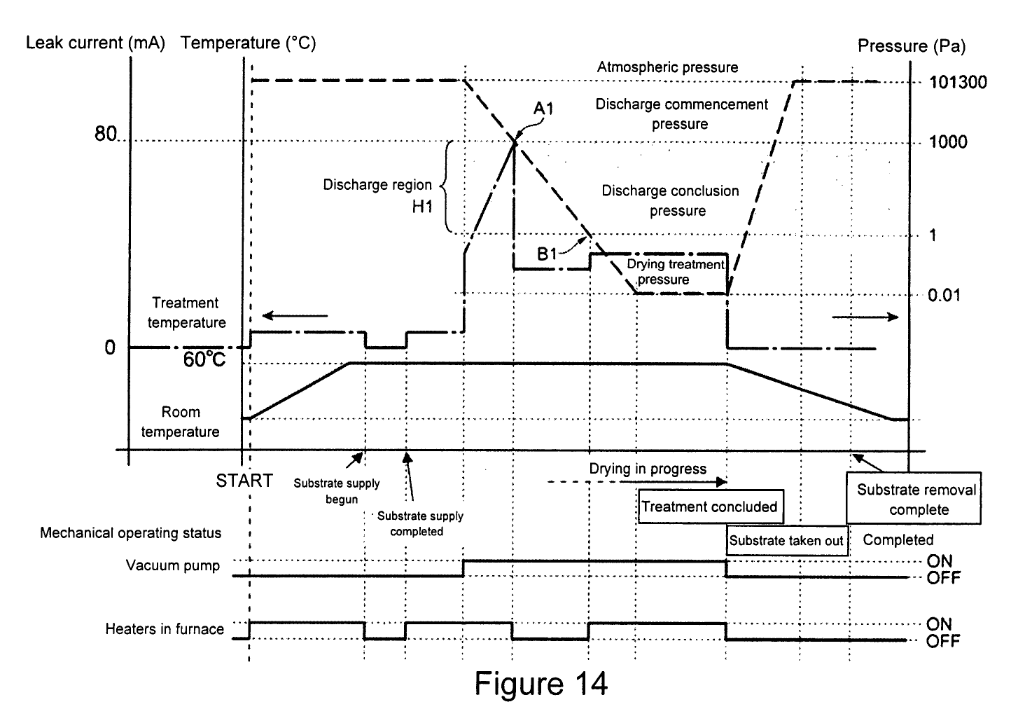

The drying apparatus 100 is constituted as above, and how the substrate 12 is dried (baked) using this drying apparatus 100 will now be described. FIG. 13 is a simplified flowchart of the procedure in operating the drying apparatus 100. FIG. 14 is a timing chart for the drying apparatus 100.

When a start work directive is given, the CPU 145 sends a signal to the input/output unit 141, the substrate supply unit 130 is operated so that the substrate 12 is transported to the holder 111, and the substrate 12 is subjected to a drying treatment by the heaters 112 under reduced pressure (see FIGS. 11A and 11B). The drying method will be described below in more specific terms.

The control panel 140 attached to the drying apparatus 100 is used to switch on the heaters 112 and turn on the furnace heaters (step S71 in FIG. 13). After this, the thermocouple 113 checks whether the temperature in the housing chamber 119 has reached the set temperature (step S72 in FIG. 13). Heating is continued if the detected temperature has yet to reach the set temperature (60° C. in this case).

Once the temperature in the housing chamber 119 reaches the set temperature, the substrate supply unit 130 attached to the input/output unit 141 is operated with the door 114 open, the pneumatic cylinder 133 moves up or down (Y2 direction), and a pneumatic cylinder (not shown) moves left or right (X2 direction) to position the substrate 12 on the holder 111 of the housing chamber 119. The door 114 is closed to complete substrate supply (step S73 in FIG. 13).

Next, the vacuum pump 116 is operated to commence pressure control by reducing the pressure inside the housing chamber 1 19 from atmospheric pressure (step S74 in FIG. 13). Temperature control is begun and the system remains on standby until the inside the housing chamber 119 reaches the specified temperature (step S75 in FIG. 13).

The detection signal from the leakage detection unit 118 is used to determine that a discharge region H1 has been entered. A leak current value at the time the pressure is the discharge commencement pressure A1 is stored in the RAM 146, and the leakage detection unit 118 shown in FIG. 12 is used to find whether the leak current value is within a permissible leak current range (step S76 in FIG. 13, discharge commencement pressure Al in FIG. 14). If the leak current value is within the permissible range, the inside of the housing chamber 119 can be reduced in pressure and heated. Once the leak current value exceeds the discharge commencement pressure A1, power to the heaters 112 is switched off. Specifically, temperature control is halted (step S77 in FIG. 13). When the heaters 112 are shut off, the leak current drops in the discharge region H1, falling from the position of the discharge commencement pressure A1 shown in FIG. 14. In view of this, the pressure value at the discharge conclusion pressure B1 is stored ahead of time in the RAM 146, and the pressure inside the housing chamber 119 is checked to see if it has dropped to the discharge conclusion pressure B1 (step S78 in FIG. 13). The reduced pressure in the housing chamber 119 can be continued if the pressure in the housing chamber 119 is too high.

Once the pressure drops to the discharge conclusion pressure B1, power to the heaters 112 is switched back on, the inside of the housing chamber 119 is heated, and temperature control is begun (step S79 in FIG. 13). The substrate 12 is dried for a specific length of time under reduced pressure (step S80 in FIG. 13). After drying has been performed for this specific time, power to the heaters 112 is switched off and temperature control is halted (step S81 in FIG. 13). At the same time, the vacuum pump 116 is stopped (pressure elevation) and pressure control is halted (step S82 in FIG. 13).

Finally, the door 114 of the drying apparatus 100 is opened, and the substrate 12 is removed from the housing chamber 119 (step S83 in FIG. 13).

The temperature control operation component 142, which is connected as shown in FIG. 12 to the thermocouple 113 for sensing the temperature of the housing chamber 1 9, and to the heaters 112 used for heating, uses the detection result of the thermocouple 113 to compute the temperature and controls the temperature inside the housing chamber 119. The input/output unit 141, which is connected to the pressure sensor 117 and the vacuum pump 116, uses the detection result from the pressure sensor 117 to control the pressure inside the housing chamber 119. These functions are implemented by program software that uses the CPU 145. The RAM 146 can store data such as the temperature and pressure inside the housing chamber 119, or the storage area for storing the program software that sets forth the control procedure for operating the drying apparatus 100.

In the timing chart of FIG. 14, the vertical axes on the left side show the temperature (° C.) and leak current (mA), while the vertical axis on the right side shows the pressure (Pa). The horizontal axis is the timing at which power to the vacuum pump 116 and the heaters 112 are switched on or off. The upper part of FIG. 14 shows the temperature, pressure, and leak current. In this graph, the solid line is the change in temperature over time, the dashed line is the change in pressure over time, and the one-dot chain line is the change in leak current over time.

When power to the heaters 112 is switched on and the inside of the housing chamber 119 is heated from room temperature up to the treatment temperature (about 60° C. in this case), this yields the temperature versus time curve shown by the solid line. Power to the heaters 112 is then switched off temporarily, the door 114 is opened, and the substrate 12 is housed in the housing chamber 119.

The door 114 is closed, power to the heaters 112 is switched back on, and the inside of the housing chamber 119 is heated. Then the vacuum pump 116 is operated to reduce the pressure in the housing chamber 119. The degree of vacuum inside the housing chamber 119 begins to rise, and the pressure in the housing chamber 119 drops so as to give the pressure versus time curve shown by the dashed line. The point of intersection between the leak current versus time curve shown by the one-dot chain line and the pressure versus time curve shown by the dashed line is the discharge commencement pressure Al, at which the leak current (discharge current value) exceeds the maximum permissible value (80 mA). If pressure reduction is continued further, the pressure inside the housing chamber 119 will keep dropping to the discharge conclusion pressure B1 at which discharge is concluded. If pressure reduction is allowed to continue, the pressure will drop to 0.01 Pa, which is a drying treatment pressure at which a stable drying treatment is possible. Between the discharge commencement pressure A1 and the discharge conclusion pressure B1 is the discharge region H1 in which discharge occurs.

The rated sensitivity current of a leak blocker is set to 100 mA, and the apparatus is designed to shut down when this leak blocker goes to work.

The leak current detection value at the discharge commencement pressure A1 is set to approximately 80% (80 mA) with respect to a rated sensitivity current of 100 mA so that the drying apparatus 100 will not shut down while the substrate 12 is being dried. This leak current detection value is pre-set in the RAM 146. Similarly, the detected pressure value at the conclusion of discharge is 1 Pa, and this value is pre-set in the RAM 146. Once the maximum permissible value of leak current reaches 80 mA, power to the heaters 112 is switched off, and one the pressure value of the discharge conclusion pressure B1 reaches 1 Pa, power to the heaters 112 is switched on.

The leak current detection value is not limited to 80 mA (approximately 80%), however, and can be set as desired. For instance, if the detection value is set lower than 80 mA, the range of the discharge region H1 will be narrower, which reduces the probability that the leak blocker will come on and the apparatus will shut down in the event that more current than normal should flow transiently to the heaters 112. On the other hand, if the detection value is set higher than 80 mA, the range of the discharge region H1 will be wider, affording a greater margin, so the period when the temperature is temporarily unstable will be shorter, which means that such instability will have less effect on product quality. Further, the pressure detection value at the discharge conclusion pressure B1 is not limited to 1 Pa, and can be set as desired. For instance, if the detection value is set lower than 1 Pa, the range of the discharge region H1 will be narrower, which reduces the probability that the leak blocker will come on and the apparatus will shut down in the event that more current than normal should flow transiently to the heaters 112. On the other hand, if the detection value is set higher than 1 Pa, the range of the discharge region H1 will be wider, affording a greater margin, so the period when the temperature is temporarily unstable will be shorter, which means that such instability will have less effect on product quality. Furthermore, since the power to the heaters 112 can be switched on sooner, the substrate 12 can be dried faster.

Next, the substrate 12 is heated and dried for a specific length of time (approximately 15 minutes in this case) at a drying treatment pressure of 0.01 Pa and a temperature of 60° C. After the specific time has elapsed, the vacuum pump 116 and the heaters 112 are switched off. The substrate 12 can be removed once the temperature inside the housing chamber 119 falls and the inside of the housing chamber 119 reaches atmospheric pressure.

The following effects are obtained with the above first embodiment.

When the vacuum pump 116 and the heaters 112 are operated so that the substrate 12 is heated and dried while the housing chamber 119 is put under reduced pressure, power to the heaters 112 can be cut off before the leak current that is generated reaches the discharge region exceeding the maximum permissible value, which prevents the leak blocker from coming on and shutting down the apparatus, so there is less effect on product quality.

Since the temperature control operation component can switch back on the power to the heaters 112, the drying treatment can be continued without affecting the quality of the substrate 12 that is being dried, so more stable quality can be achieved.

Since the heaters 112 can be shut off after checking the leak current value, the temperature can be accurately controlled once the maximum permissible value is reached, so the leak blocker will not shut down the apparatus because of the timing at which the power to the heaters 112 is switched off.

### Second Embodiment

A second embodiment of the invention will now be described. This second embodiment differs from the first embodiment above in the detection method, that is, in that the pressure value is detected instead of the leak current value when the power is cut off. The same drying apparatus 100 as in the first embodiment is used here again, and will therefore not be described again.

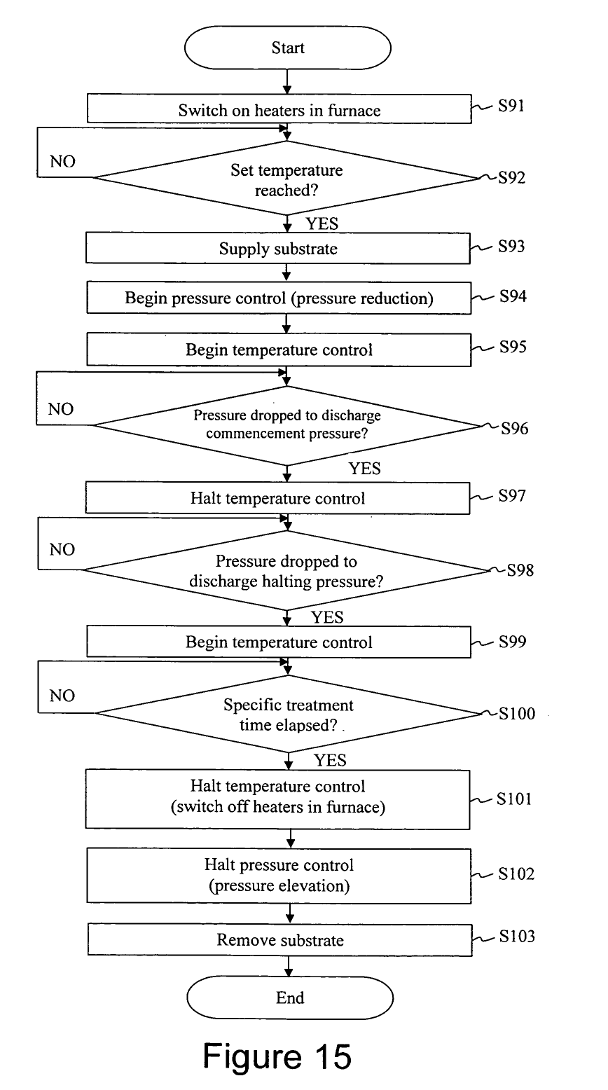

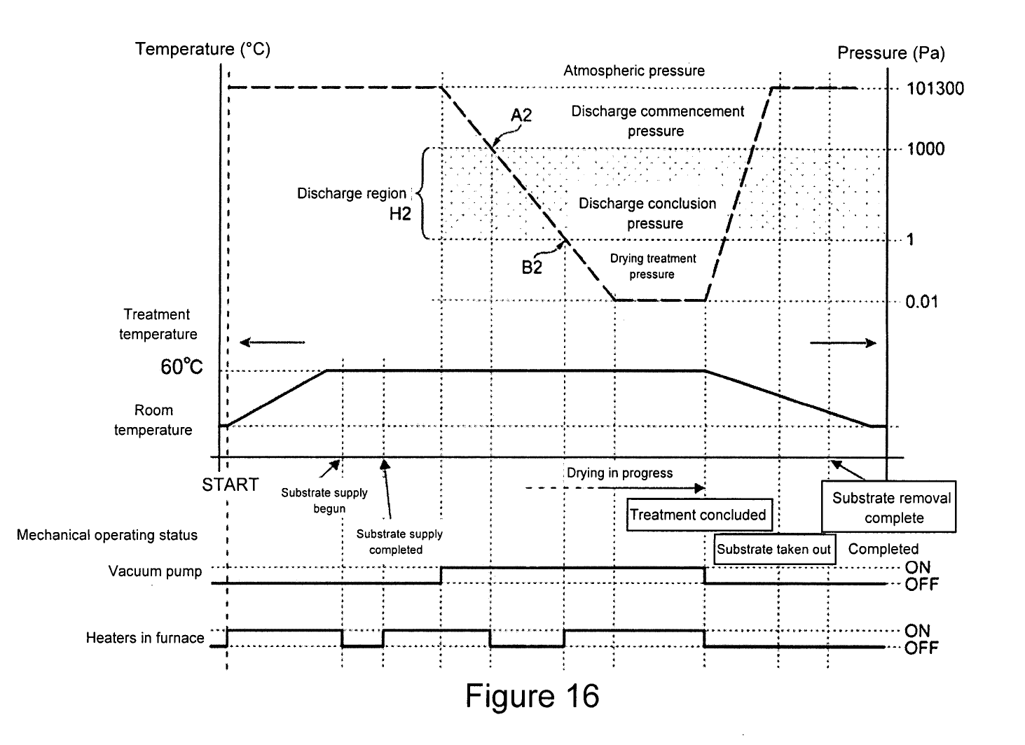

The drying (baking) method used in the second embodiment will be described. FIG. 15 is a simplified flowchart of the procedure followed in the operation of the drying apparatus 100. FIG. 16 is a timing chart of the drying apparatus 100.

The control panel 140 attached to the drying apparatus 100 is used to switch on the heaters 112 and turn on the furnace heaters (step S91 in FIG. 15). After this, the thermocouple 113 checks whether the temperature in the housing chamber 119 has reached the set temperature (step S92 in FIG. 15). Heating is continued if the detected temperature has yet to reach the set temperature (60° C. in this case).

Once the temperature in the housing chamber 119 reaches the set temperature, the substrate supply unit 130 attached to the input/output unit 141 is operated with the door 114 open, the pneumatic cylinder 133 moves up or down (Y2 direction), and a pneumatic cylinder (not shown) moves left or right (X2 direction) to position the substrate 12 on the holder 111 of the housing chamber 119. The door 114 is closed to complete substrate supply (step S93 in FIG. 15).

Next, the vacuum pump 116 is operated to commence pressure control by reducing the pressure inside the housing chamber 119 from atmospheric pressure (step S94 in FIG. 15). Temperature control is begun and the system remains on standby until the inside the housing chamber 119 reaches the specified temperature (step S95 in FIG. 15).

It is determined whether the detection value of a discharge commencement pressure A2 in a discharge region H2 is within a permissible range (step S96 in FIG. 15, discharge commencement pressure A2 in FIG. 16). If the pressure is too high inside the housing chamber 119, it can be reduced. Once the pressure detection value exceeds the discharge commencement pressure A2, power to the heaters 112 is switched off and temperature control is halted (step S87 in FIG. 15). When the power to the heaters 112 is switched off, the pressure in the discharge region H2 starts dropping from the discharge commencement pressure A2. The pressure sensor 117 shown in FIG. 12 is used to determine whether the pressure has dropped to a discharge conclusion pressure B2 (step S98 in FIG. 15). If the pressure is too high inside the housing chamber 119, it can be reduced.

Once the pressure drops to the discharge conclusion pressure B2, power to the heaters 112 is switched back on, the inside of the housing chamber 119 is heated, and temperature control is begun (step S99 in FIG. 15). The substrate 12 is dried for a specific length of time under reduced pressure (step S100 in FIG. 15). After drying has been performed for this specific time, power to the heaters 112 is switched off and temperature control is halted (step S101 in FIG. 15). At the same time, the vacuum pump 116 is stopped (pressure elevated) and pressure control is halted (step S102 in FIG. 15).

Finally, the door 114 of the drying apparatus 100 is opened, and the substrate 12 is removed from the housing chamber 119 (step S103 in FIG. 15).

In the timing chart of FIG. 16, the vertical axis on the left side shows the temperature (° C.), while the vertical axis on the right side shows the pressure (Pa). The horizontal axis is the timing at which power to the vacuum pump 116 and the heaters 112 are switched on or off. The upper part of FIG. 16 shows the temperature and pressure, and in this graph, the solid line is the change in temperature over time, while the dashed line is the change in pressure over time.

Power to the heaters 112 is switched on and the inside of the housing chamber 119 is heated from room temperature up to the treatment temperature (about 60° C. in this case). Power to the heaters 112 is then switched off temporarily, the door 114 is opened, and the substrate 12 is housed in the housing chamber 119.

The door 114 is closed, power to the heaters 112 is switched back on, and the inside of the housing chamber 119 is heated. Then the vacuum pump 116 is operated to reduce the pressure in the housing chamber 119. The degree of vacuum inside the housing chamber 119 begins to rise, and the pressure in the housing chamber 119 drops so as to give the pressure versus time curve shown by the dashed line. The pressure value of the discharge commencement pressure A2 at which discharge begins is 1000 Pa. If pressure reduction is continued further, the pressure inside the housing chamber 119 will keep dropping to the discharge conclusion pressure B2 at which discharge is concluded. If pressure reduction is allowed to continue, the pressure will drop to 0.01 Pa, which is a drying treatment pressure at which a stable drying treatment is possible. Between the discharge commencement pressure A2 and the discharge conclusion pressure B2 is the discharge region H2 in which discharge occurs.

The discharge commencement pressure A2 when the degree of vacuum in the housing chamber 119 rises and discharge begins is 1000 Pa, and this pressure detection value is pre-set in the pressure sensor 117. The discharge conclusion pressure B2 when discharge is concluded is 1 Pa, and this pressure detection value is pre-set in the pressure sensor 117. Once the discharge commencement pressure A2 reaches 1000 Pa, power to the heaters 112 is switched off, and once the discharge conclusion pressure B2 reaches 1 Pa, power to the heaters 112 is switched on.

The pressure detection value at the discharge commencement pressure A2 is not limited to 1000 Pa, and can be set as desired. For instance, if the pressure detection value is set higher than 1000 Pa, the range of the discharge region H2 will be narrower,⁴ which reduces the probability that the leak blocker will come on and the apparatus will shut down in the event that more leak current than normal should flow transiently to the heaters 112. On the other hand, if the pressure detection value is set higher than 1000 Pa, the furnace heaters will be off for a shorter time, and the period when the temperature is temporarily unstable will be shorter, which means that such instability will have less effect on product quality. Further, the pressure detection value at the discharge conclusion pressure B2 is not limited to 1 Pa, and can be set as desired. For instance, if the pressure detection value is set lower than 1 Pa, the range of the discharge region H2 will be narrower,⁴ which reduces the probability that the leak blocker will come on and the apparatus will shut down in the event that leak current should flow transiently. On the other hand, if the pressure detection value is set higher than 1 Pa, the range of the discharge region H1 will be wider, affording a greater margin, so the period when the temperature is temporarily unstable will be shorter, which means that such instability will have less effect on product quality. Furthermore, since the power to the heaters 112 can be switched on sooner, the substrate 12 can be dried faster.

Next, the substrate 12 is heated and dried for a specific length of time (approximately 15 minutes in this case) at a drying treatment pressure of 0.01 Pa and a temperature of 60° C. After the specific time has elapsed, the vacuum pump 116 and the heaters 112 are switched off. The substrate 12 can be removed once the temperature inside the housing chamber 119 falls and the inside of the housing chamber 119 reaches atmospheric pressure.

The following effect is obtained with the above second embodiment, in addition to those obtained with the first embodiment.

Since power to the heaters 112 can be switched on and off using the pressure sensor 117, the leakage detection unit 118 need not be used. The result is a simpler structure of the drying apparatus 100.

The invention was described above through preferred embodiments, but the invention is not limited to the embodiments given above, and also encompasses the following modifications, and all other specific structures and shapes can be employed as long as the object of the invention can still be attained.

Modification 1

The drying apparatus 100 used in the first and second embodiments above is not limited to the above-mentioned EL apparatus or color filter. For instance, it can instead be an FED (Field Emission Display) or other such electron emission apparatus, a PDP (Plasma Display Panel), an electrophoresis apparatus (that is, an apparatus in which a material that is a functional liquid containing charged particles is discharged into recesses between the barriers of pixels, and voltage is applied between electrodes provided flanking the pixels above and below, so that the charged particles are gathered on one electrode side and the pixels form a display), a thin CRTs (Cathode Ray Tubes), regular CRTs, and other such display devices (electro-optical devices) having a substrate and involving a step of forming a specific layer in a region over this substrate.

Modification 2

Also, the above-mentioned substrate is not the only thing that the drying apparatus 100 can be used to manufacture. For instance, it may be another solid besides a substrate. Since many different kinds of object can thus be heated and dried under reduced pressure, the drying apparatus 100 has a wide range of potential applications.

Modification 3

The application of the drying apparatus 100 is not limited to the drying work discussed above. For instance, it may be used for the sinter of ceramics, metals, and so forth, the heating and curing of adhesives and resins, the heating and curing of flowables, and so on. Since many different kinds of object can thus be heated under reduced pressure, the drying apparatus 100 has a wide range of potential applications.

Modification 4

In the first and second embodiments above, the pressure was reduced while heating was performed, but the invention is not limited to this. For instance, the order may be reversed so that heating is performed while the pressure is reduced. This will yield the same effects as in the first and second embodiments.

This application claims priority to Japanese Patent Application No. 2004-364102. The entire disclosure of Japanese Patent Application No. 2004-364102 is hereby incorporated herein by reference.

1. A heating furnace comprising
a housing chamber adapted to house a heating object,
a heater for heating the heating object housed in the housing chamber,
a vacuum pump for reducing a pressure inside the housing chamber,
a pressure detector for detecting the pressure inside the housing chamber;
a leakage detector for detecting any leak current that is caused by reducing the pressure inside the housing chamber while power is supplied to the heater; and
a controller for switching the power to the heater on or off on the basis of detection results from the pressure detector and the leakage detector.

2. The heating furnace according to claim 1, wherein
the controller stops the flow of power to the heater while the heating furnace is within a discharge region, the discharge region being a reduced pressure region in which at least the leak current exceeds a permissible value during a pressure reduction process to reduce the pressure inside the housing chamber.

3. The heating furnace according to claim 2, wherein
the controller switches off the power to the heater once the leak current detected by the leakage detector reaches a set current value that is at or below the permissible value, and
the controller switches on the power to the heater once the pressure inside the housing chamber as detected by the pressure detector reaches a set pressure value that is below a lower limit of the discharge region.

4. The heating furnace according to claim 2, wherein
the controller switches off the power to the heater once the pressure inside the housing chamber as detected by the pressure detector reaches a first set value that is above the upper limit of the discharge region, and
the controller switches on the power to the heater once the pressure reaches a second set value that is below the lower limit of the discharge region.

5. A method for drying a substrates to a specific region of which a functional liquid has been applied, the method comprising:
reducing a pressure inside a housing chamber;
heating a heating object in the housing chamber with a heater;
switching off power to the heater once a leak current detection value, which is generated as the pressure inside the housing chamber is reduced while the power is supplied to the heater, reaches a set current value; and
switching on the power to the heater once the pressure in the housing chamber is further reduced after the heater has been switched off, and the detected value of the pressure inside the housing chamber reaches a set pressure value.

6. A method for drying a substrate, to a specific region of which a functional liquid has been applied, the method comprising:
reducing a pressure inside a housing chamber;
heating a heating object in the housing chamber with a heater;
switching off power to the heater once the pressure in the housing chamber is reduced to a first set value while the power is supplied to the heater; and
switching on the power to the heater once the pressure in the housing chamber is further reduced after the heater has been switched off, and the detected value of the pressure inside the housing chamber reaches a second set value.

7. The method for drying a substrate according to claim 5, wherein
in the switching off of the power to the heater, the current value is 80 mA.

8. The method for drying a substrate according to claim 6, wherein
in the switching off of the power to the heater, the pressure value is 1000 Pa.

9. The method for drying a substrate according to claim 5, wherein
in the switching on the power to the heater, the pressure value is 1 Pa.

10. A method for manufacturing a device in which pixels are formed on a substrate by a droplet discharge method, wherein
the drying method according to claim 5 is used.
